(19) United States
(12) Patent Application Publication
(10) Pub. No.: US 2026/0237440 A1
(43) Pub. Date: Aug. 13, 2026

(54) MEMORY DEVICE AND MEMORY OPERATION METHOD

(71) Applicant: MACRONIX INTERNATIONAL CO., LTD., HSINCHU (TW)

(72) Inventor: Yu-Yu LIN, New Taipei City (TW)

(21) Appl. No.: 19/049,068

(22) Filed: Feb. 10, 2025

(51) Int. Cl. G11C 16/26; G06F 17/16; G11C 16/04

(52) U.S. Cl. CPC G11C 16/26; G06F 17/16; G11C 16/0483

(57) ABSTRACT

A memory operation method, comprising: obtaining, by a processing circuit, an operation code of a vector-matrix multiplication, wherein the processing circuit is coupled to a memory array, the memory array comprises a plurality of memory strings, and the operation code comprises a plurality of operation bits; converting a first partition of the plurality of operation bits into a first conversion code, wherein a format of the first conversion code is different from a format of the operation code; and using the first conversion code and a second partition of the plurality of operation bits as an input data, and inputting the input data to a corresponding one of the plurality of memory strings, so that the plurality of memory strings generates an output signal according to a plurality of weight values.

### BACKGROUND

### Technical Field

The present disclosure relates to a memory operation method, particularly a memory device capable of performing vector-matrix multiplication.

### Description of Related Art

As the computing speed of computers increases, the requirements for memory speed and stability are getting higher and higher. With many different market demands, how to improve the application of memory so that it can not only read and write data, but also be used as part of computing processing has become a major topic at present.

### SUMMARY

One aspect of the present disclosure is a memory operation method, comprising: obtaining, by a processing circuit, an operation code of a vector-matrix multiplication, wherein the processing circuit is coupled to a memory array, the memory array comprises a plurality of memory strings, and the operation code comprises a plurality of operation bits; converting a first partition of the plurality of operation bits into a first conversion code, wherein a format of the first conversion code is different from a format of the operation code; and using the first conversion code and a second partition of the plurality of operation bits as an input data, and inputting the input data to a corresponding one of the plurality of memory strings, so that the plurality of memory strings generates an output signal according to a plurality of weight values. Accordingly, by dividing the operation bits into multiple partitions, the noise reduction ratio can be improved while still ensuring transmission efficiency.

In one embodiment, the first partition comprises a most significant bit of the plurality of operation bits. Since the higher-order bits in a binary sequence, when affected by transmission noise, result in larger errors, converting the format of the most significant bit will improve the noise reduction ratio during calculation.

In one embodiment, the first partition of the plurality of operation bits has higher-order bits compared to the second partition. As mentioned above, the higher-order bits in a binary sequence, when affected by transmission noise, result in larger errors, so this method can improve the noise reduction ratio during calculation.

In one embodiment, a number of bits in the first partition accounts for 40% to 60% of the plurality of operation bits. Accordingly, the transmission time will be effectively controlled.

In one embodiment, a number of bits in the first partition is larger than a number of bits in the second partition. Accordingly, after converting the first partition in a unary encoding format, the characteristics of unary encoding will be more fully utilized and noise interference will be reduced.

In one embodiment, a number of bits in the first partition accounts accounts for 70% to 95% of the plurality of operation bits. Accordingly, the characteristics of unary encoding will be more fully utilized and noise interference will be reduced.

In one embodiment, using the first conversion code and the second partition of the plurality of operation bits as the input data comprises: converting the second partition of the plurality of operation bits into a second conversion code, wherein a format of the second conversion code is equal to the format of the first conversion code. Accordingly, the noise reduction ratio during calculation can be improved.

In one embodiment, the format of the first conversion code is in unary encoding format. The format of unary code can reduce the impact of noise in signal transmission.

In one embodiment, the format of the operation code is in binary encoding format. The format of binary code can ensure the transmission efficiency.

In one embodiment, the memory operation method further comprises: receiving a plurality of output currents of the plurality of memory strings; and calculating a current sum value of the plurality of output currents to obtain the output signal. By summing the current values of the memory strings, the memory array can be used to complete the vector-matrix multiplication.

Another aspect of the present disclosure is a memory device, comprising a memory array, a sensing circuit and a processing circuit. The memory array is coupled to a plurality of word lines and a plurality of bit lines, and comprises a plurality of memory strings. The sensing circuit is coupled to the memory array to obtain an output signal from the memory array. The processing circuit is coupled to the memory array, and is configured to generate an operation code according to an operation data of a vector-matrix multiplication. The operation code comprises a plurality of operation bits. The processing circuit is further configured for: converting a first partition of the plurality of operation bits into a first conversion code, wherein a format of the first conversion code is different from a format of the operation code; and using the first conversion code and a second partition of the plurality of operation bits as an input data, and inputting the input data to a corresponding one of the plurality of memory strings, so that the plurality of memory strings generates an output signal according to a plurality of weight values. Accordingly, by dividing the operation bits into multiple partitions, the noise reduction ratio can be improved while still ensuring transmission efficiency.

In one embodiment, the first partition comprises a most significant bit of the plurality of operation bits. Since the higher-order bits in a binary sequence, when affected by transmission noise, result in larger errors, converting the format of the most significant bit will improve the noise reduction ratio during calculation.

In one embodiment, the first partition of the plurality of operation bits has higher-order bits compared to the second partition. As mentioned above, the higher-order bits in a binary sequence, when affected by transmission noise, result in larger errors, so this method can improve the noise reduction ratio during calculation.

In one embodiment, a number of bits in the first partition accounts for 40% to 60% of the plurality of operation bits. Accordingly, the transmission time will be effectively controlled.

In one embodiment, a number of bits in the first partition is larger than a number of bits in the second partition. Accordingly, after converting the first partition in a unary encoding format, the characteristics of unary encoding will be more fully utilized and noise interference will be reduced.

In one embodiment, a number of bits in the first partition accounts for 70% to 95% of the plurality of operation bits. Accordingly, the characteristics of unary encoding will be more fully utilized and noise interference will be reduced.

In one embodiment, the processing circuit is further configured for: converting the second partition of the plurality of operation bits into a second conversion code, wherein a format of the second conversion code is equal to the format of the first conversion code. Accordingly, the noise reduction ratio during calculation can be improved.

In one embodiment, the format of the first conversion code is in unary encoding format. The format of unary code can reduce the impact of noise in signal transmission.

In one embodiment, the format of the operation code is in binary encoding format. The format of binary code can ensure the transmission efficiency.

In one embodiment, the sensing circuit is further configured for: receiving a plurality of output currents of the plurality of memory strings; and calculating a current sum value of the plurality of output currents to obtain the output signal. By summing the current values of the memory strings, the memory array can be used to complete the vector-matrix multiplication.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a memory device in some embodiments of the present disclosure.

FIG. 2 is a schematic diagram of a memory string in some embodiments of the present disclosure.

FIG. 3A is a schematic diagram of the operation code in some embodiments of the present disclosure.

FIG. 3B is a schematic diagram of the operation code in some embodiments of the present disclosure.

FIG. 4 is a schematic diagram of the operation code in some embodiments of the present disclosure.

FIG. 5 is a flowchart illustrating a memory operation method in some embodiments of the present disclosure.

FIG. 6 is a schematic diagram of a modified array in some embodiments of the present disclosure.

FIG. 7A is a schematic diagram of the operation of the memory device in some embodiments of the present disclosure.

FIG. 7B is a schematic diagram of the operation of the memory device in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

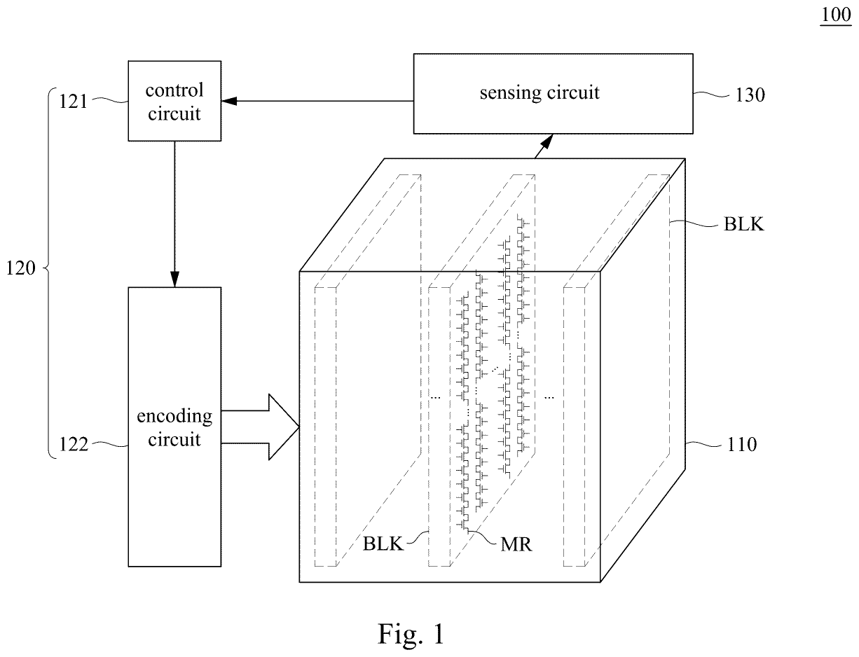

FIG. 1 is a schematic diagram of a memory device 100 in some embodiments of the present disclosure. The memory device 100 is configured to implement “In Memory Computing” (IMC), and performs a vector-matrix multiplication (VMM), such as the Multiply-and-Accumulate (MAC) calculation commonly used in artificial intelligence (AI) technology.

The memory device 100 includes a memory array 110, a processing circuit 120 and a sensing circuit 130. The memory array 110 is coupled to the processing circuit 120 through multiple word lines and multiple bit lines, and includes the multiple memory blocks BLK. Each of the memory blocks BLK includes multiple memory strings MR, and each of the memory strings MR includes multiple memory units (memory cell). In one embodiment, the memory string MR can be a kind of NAND string.

The processing circuit 120 is coupled to the memory array 110 through the word lines and the bit lines to provide data about the vector-matrix multiplication. In one embodiment, the processing circuit 120 can include a control circuit 121 and an encoding circuit 122, the control circuit 121 is configured to provide an original data of the vector-matrix multiplication, and the encoding circuit 122 is configured to encode the original data to input to the memory array 110. The circuit structure of the processing circuit 120 is not limited to the structure shown in FIG. 1. In the subsequent paragraphs, the execution step of the processing circuit 120 may be performed by either the control circuit 121 or the encoding circuit 122.

When performing the vector-matrix multiplication, the processing circuit 120 is configured to provide the input data of the vector-matrix multiplication (hereinafter referred to as “operation data”) through the word lines and the bit lines to the memory array 110. The memory array 110 generates an output signal (e.g., output current) according to multiple weight values preset internally.

The sensing circuit 130 is coupled to the memory array 110, and is configured to receive the output signal from the memory array 110. In one embodiments, the sensing circuit 130 receives multiple output currents of the memory strings MR, and calculates a current sum value of all output currents to generate the output signal. In one embodiments, the sensing circuit 130 also calculates a impedance sum value according to the current sum value as the output signal (i.e., calculation result).

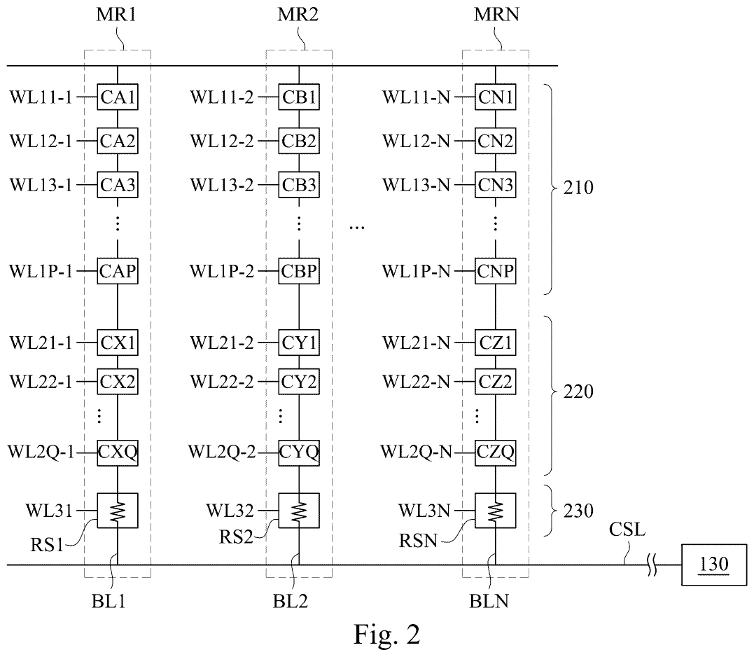

FIG. 2 is a schematic diagram of multiple memory strings in some embodiments of the present disclosure. The memory strings MR1-MRN can be implemented to any one of the memory blocks BLK shown in FIG. 1. The memory strings MR1-MRN shown in FIG. 2 are two-dimensional structures, but in other embodiments, the memory blocks BLK may include a three-dimensional memory string structure.

Referring to FIG. 1 and FIG. 2, the memory strings MR1-MRN respectively include multiple memory units CA1-CAP, CB1-CBP, CN1-CNP, each memory unit is set to have a weight value. Taking “Multiply-and-Accumulate calculation” as an example, “weight value” can be a product coefficient used in artificial intelligence/neural networks. “Weight value” can be determined by the respective conductance value (or impedance value) of each memory unit, and the conductance value of the memory unit depends on its threshold voltage. By applying voltage to each memory unit, the amount of charge in the floating gate can be controlled to change the threshold voltage.

Taking the structure shown in FIG. 2 as an example, the operation of the memory string when performing the vector-matrix multiplication is as follows: in one embodiment, the memory strings MR1-MRN receive a read voltage through the bit lines BL1-BLN, and receive the respective operation data through the respective word lines WL11-1~WL1P-1, WL11-2~WL1P-2, WL11-N~WL1P-N (e.g., the word line WL11-1 provides the respective operation data to the memory unit CA1, the word line WL11-2 provides the respective operation data to the memory unit CB1). Each of the memory strings MR1-MRN generates a unit current according to the preset weight values and the received read voltage, and all unit currents outputs to the sensing circuit 130 through a common source line CSL to calculate result. In one embodiment, the processing circuit 120 can generate an operation code (e.g., binary code) according to each operation data, and uses the operation codes as a digital voltage signal, the details will be detailed in the subsequent paragraphs.

In some embodiments, the above weight value can include multiple calculation weight values, at least one balanced weight value and at least one series weight value. The memory units CA1-CAP, CB1-CBP, CN1-CNP in the memory string can be used as multiple calculation weight unit 210, and are configured to be set the calculation weight values. Each memory string further includes at least one balanced weight unit 220 and at least one series weight unit 230. The balanced weight unit 220 is configured to adjust the equivalent impedance value of each memory string, and is configured to be adjust the standard deviation of all weight values. The impedance value of the series weight unit 230 depends on the overall impedance of each memory string, and the series weight unit 230 is configured to make each memory string have a basic impedance value. In other words, the balanced weight unit 220 and the series weight unit 230 are not configured to perform Multiply-and-Accumulate calculation directly, but are configured to adjust the overall impedance of the corresponding memory string to make the calculation result of the sensing circuit 130 more accurate.

Specifically, the calculation weight unit 210 and the balanced weight unit 220 can be implemented with the same type of memory unit, such as the transistor units CX1-CXQ, CY1-CYQ and CZ1-CZQ shown in FIG. 2. The balanced weight unit 220 of the memory strings can also receive a respective setting signal through the respective word lines WL21-1~WL2Q-1, WL21-2~WL2Q-2, WL21-N~WL2Q-N to set the respective balanced weight values. The series weight unit 230 can be implemented by the impedance elements RS1-RSN (e.g., resistors), and can receive a respective setting signal through the respective word lines WL31~WL3N to set the respective series weight value.

For ease of understanding, the input method of the processing circuit 120 to input “operation data” (i.e., input values of the vector-matrix multiplication) is explained here. The processing circuit 120 converts an operation data into an operation code, and each operation code includes multiple operation bits. The processing circuit 120 inputs the operation codes into the corresponding memory string to calculate. For example, the operation data used to perform the vector-matrix multiplication includes multiple values, such as “9, 4, 11, 10, 6, 4, 10, 4, 9, 10, 15, 9, 12, 9, 14, 9, 12, 11, 7, 5”, and the processing circuit 120 converts each operation data into a specific format code and applies a digital voltage signal to the corresponding memory string.

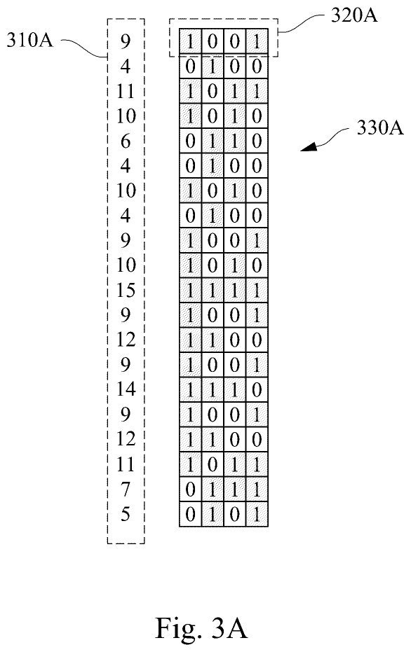

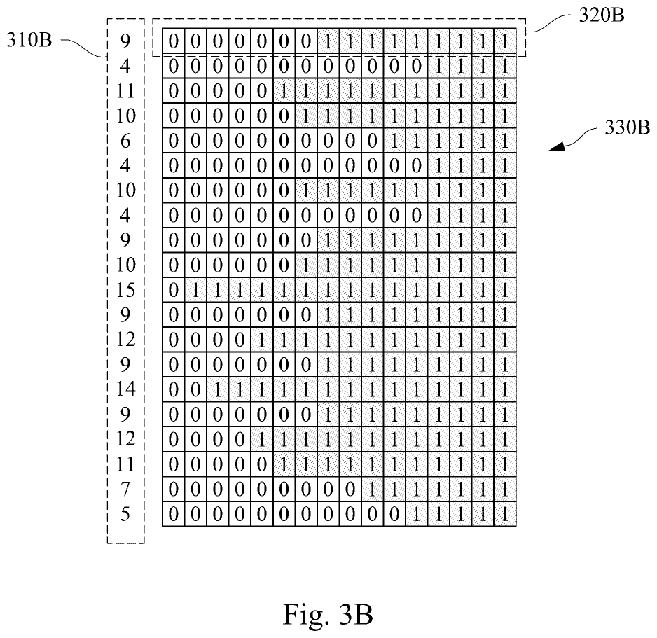

The operation codes generated by the processing circuit 120 can be represented by an encoded array. FIG. 3A is a schematic diagram of the encoded array 330A in some embodiments of the present disclosure. In this embodiment, the operation data 310A includes “9, 4, 11, 10, 6, 4, 10, 4, 9, 10, 15, 9, 12, 9, 14, 9, 12, 11, 7, 5”, and the processing circuit 120 converts the operation data 310A into a binary encoding format. For example, when “9” in the operation data 310A is converted into a binary encoding format, the corresponding operation code 320A is “1, 0, 0, 1” including four operation bits, and all the operation codes can be organized into an encoded array 330A. When performing the calculation, the processing circuit 120 uses each column of the encoded array 330A as a unit, and inputs each bit of each operation code into the corresponding memory string(s).

However, due to the non-ideal characteristics of electronic components and the noise in signal transmission, the calculation result of the vector-matrix multiplication will have some errors. Data in binary encoding format are very sensitive to noise in calculations, which can easily cause excessive errors in the calculation result. Therefore, in some embodiments, the processing circuit 120 will convert the operation data in a format of Unary Code (or called Thermometer Code). The format of Unary Code can reduce the problem of serious interpretation errors caused by slight transmission errors during the transmission of the operation data.

Unary Code represents a value by “the number of bits 1”. Therefore, even if there are a few bit errors during data transmission, the actual interpreted value will not be too different from the correct value. FIG. 3B is a schematic diagram of an encoded array 330B in some embodiments of the present disclosure. In this embodiment, the operation data 310B also includes “9, 4, 11, 10, 6, 4, 10, 4, 9, 10, 15, 9, 12, 9, 14, 9, 12, 11, 7, 5”, but the processing circuit 120 converts the operation data 310B into unary encoding format. For example, when “9” in the operation data 310B is converted into a unary encoding format, the corresponding operation code 320B is “0000000111111111” including nine operation bits “1”. All operation codes 320B can be organized into an encoded array 330B, and each row of the encoded array 330B will correspond to an operation data.

Taking the aforementioned embodiment as an example, when the operation code is in a unary encoding format, the impact of transmitted noise can be reduced by 5.68 times, thus reducing the error of the calculation result. However, since the number of bits in the unary encoding format is relatively large (e.g., 16 bits), it is more time-consuming in transmission. In other words, the unary encoding format has advantages in dealing with noise, but has disadvantages in transmission time.

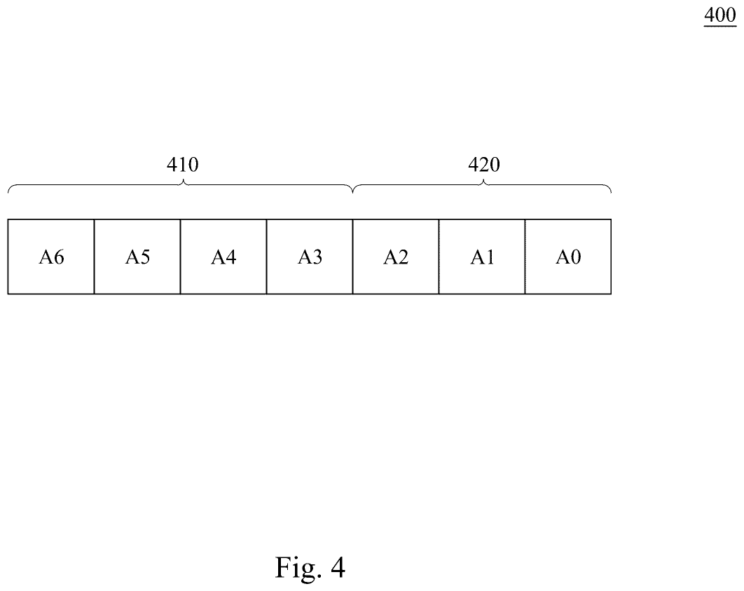

The present disclosure divides the operation code into multiple parts for processing to take into account the noise reduction ratio and transmission efficiency. FIG. 4 is a schematic diagram of the operation code 400 in some embodiments of the present disclosure. The operation code 400 includes multiple operation bits A0~A6. In one embodiment, the operation code 400 or the operation bits A0~A6 is in binary encoding format, but the present disclosure is not limited to this. The processing circuit 120 can also organize the operation bits of the operation code 400 into octal, decimal or hexadecimal formats.

The operation bits A0~A6 can be divided into a first partition 410 and a second partition 420. For example, if the operation code is “1010011”, the first partition 410 may represent the higher-order first four operation bits A6~A3 “1010”, and the second partition represents the lower-order last three operation bits A2~A0 “011”. The number of bits included in the first partition 410 and the number of bits included in the second partition 420 can be configured as needed.

The processing circuit 120 converts the first partition 410 to to other formats (e.g., unary encoding), and the second partition 420 can maintain the original format. The processing circuit 120 can also convert the second partition 420 to other formats. Accordingly, by dividing the operation bits A0~A6 into multiple partitions, the noise reduction ratio can be improved while still ensuring transmission efficiency.

For example, the decimal operation data “83” corresponds to the binary encoded operation code “1010011”. If the complete operation bits “1010011” is directly converted into a unary encoding format, there will be at least 83 bits (because 83 “1”s are needed). If the operation bits “1010011” is divided into the first partition 410 (“1010”) and the second partition 420 (“011”), four operation bits “1010” of the first partition 410 corresponds to the decimal value “10”, and the unary code is “1111111111”. Similarly, three operation bits “011” of the second partition 420 corresponds to the decimal value “3”, and the unary code is “0000000111”. Therefore, if the operation data is divided into two partitions and each partition is converted into unary encoding format, it require only at least 13 bits (ten “1”s and three “1”s). It can be seen that after dividing operation bits A0~A6 into multiple partitions, the time required for data transmission can be effectively reduced, that is, the number of bits required to be transmitted is reduced.

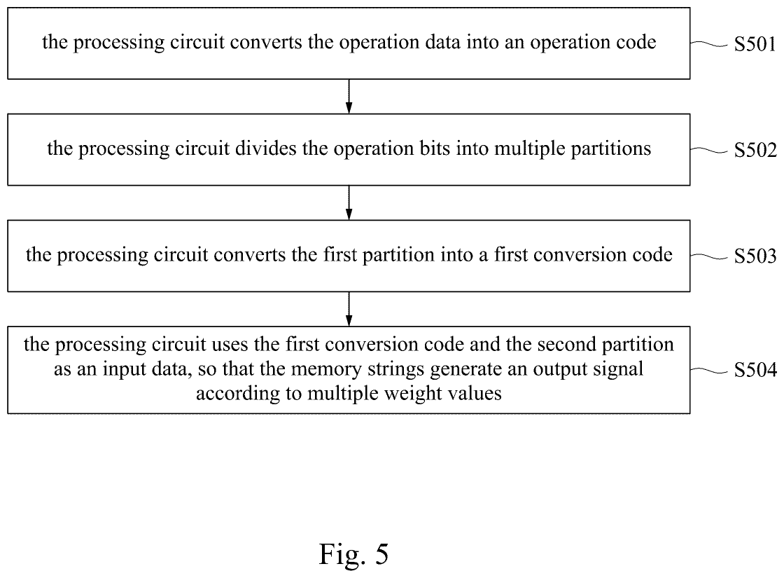

For ease of understanding, the memory operation method of the present disclosure is illustrated in FIG. 5. Referring to FIG. 1, FIG. 4 and FIG. 5, in step S501, the processing circuit 120 is configured to obtain at least one operation data (e.g., “83”) of the vector-matrix multiplication, and convert the operation data into an operation code 400. The operation code 400 includes multiple operation bits A0~A6. In some other embodiments, the processing circuit 120 can generates multiple operation codes according to multiple operation data at the same time.

In step S502, the processing circuit 120 divides the operation bits A0~A6 into multiple partitions, such as the first partition 410 and the second partition 420 shown in FIG. 4. In some embodiments, the number of bits included in the first partition 410 and the second partition 420 can be adjusted according to needs, and the division method of the operation bits can be set in the processing circuit 120 in advance.

In step S503, the processing circuit 120 converts the first partition 410 into a first conversion code, and a format of the first conversion code is different from a format of the operation code. For example, converting the binary code “1010” into unary encoding format (i.e., ten “1”s).

In step S504, the processing circuit 120 uses the first conversion code and the second partition 420 as an input data, and inputs the input data to the corresponding memory string(s) MR, so that the memory strings MR generate an output signal according to multiple weight values. The processing circuit 120 can convert the second partition 420 selectively, such as maintain the binary encoding format, or also convert into the unary encoding format.

During performing the aforementioned step S503, the processing circuit 120 can maintain the format of the second partition 420 (e.g., binary encoding format). In other words, the input data in step S504 will include multiple codes for multiple different encoding formats.

As mentioned above, in some other embodiments, during performing the aforementioned step S503, the processing circuit 120 can convert the second partition 420 into a second conversion code, and a format of the second conversion code is equal to a format of the first conversion code. For example, converting the binary operation code “011” into unary encoding format (i.e., three “1” ). In other words, all codes of the input data in step S504 is the same format. Accordingly, the noise reduction ratio of the calculation will be effectively improved.

In some embodiments, the first partition 410 of the operation bits A0~A6 includes a most significant bit (MSB). For example, if the operation bits A0~A6 is “1010011”, the first partition 410 at least includes the most significant bit (i.e., the first “1” from the left). Since the higher-order bits in a binary sequence, when affected by transmission noise, result in larger errors, converting the format of the most significant bit will improve the noise reduction ratio during calculation.

In some embodiments, the first partition 410 of the operation bits A0~A6 has higher-order bits compared to the second partition 420 of the operation bits A0~A6. Taking multiple operation bits A0~A6 “1010011” as an example, the first partition 410 is the first four operation bits “1010”, and the second partition 420 is the last three operation bits “011”. In other words, each operation bit of the first partition 410 is a higher-order bit compared to each operation bit of the second partition 420. As mentioned above, the higher-order bits in a binary sequence, when affected by transmission noise, result in larger errors, so this method can improve the noise reduction ratio during calculation.

In some embodiments, the number of bits of the first partition 410 is similar to the number of bits of the second partition 420. Accordingly, the transmission time will be effectively controlled. Taking the operation bits A0~A6 “1010011” as an example, the number of bits in the first partition 410 (4 bits) accounts for 40%~60% of all operation bits (7 bits). In other words, the ratio of either of the first partition 410 and the second partition 420 will not be too large. Therefore, when both the first partition 410 and the second partition 420 are converted into a unary encoding format, the number of bits of each converted partition will not be too many, and the transmission speed and efficiency can be ensured.

In some other embodiments, the number of bits of the first partition 410 is larger than the number of bits of the second partition 420. Taking the operation bits A0~A6 “1010011” as an example, the first six operation bits “101001” can be used as the first partition, and the last operation bit “1” can be used as the second partition. Accordingly, after converting the first partition into a unary encoding format, the characteristics of unary encoding will be more fully utilized and noise interference will be reduced. In one embodiment, the number of bits in the first partition accounts for 70% to 95% of all operation bits.

Referring to FIG. 1 and FIG. 3B, in some embodiments, before performing the method shown in of FIG. 5, the processing circuit 120 can adjust the encoded array 330B formed by the operation codes 320B, so that the distribution of bits “1” in the array is more even. The more evenly distributed the bits “1” in the array, the smaller the standard deviation of the memory string distribution, and the more accurate the computation results of the sensing circuit 130.

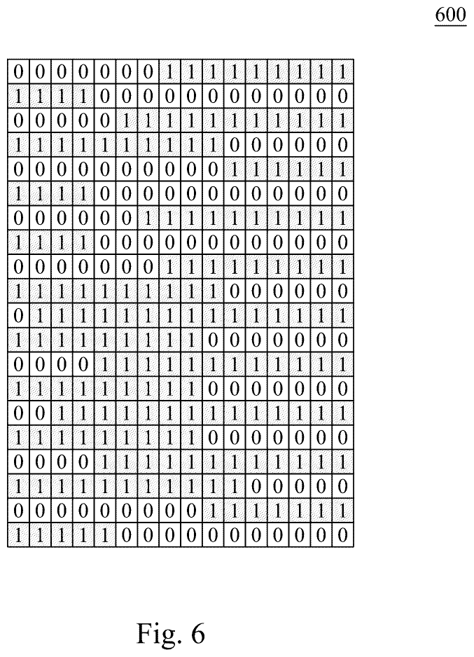

FIG. 6 is a schematic diagram of a modified array 600 in some embodiments of the present disclosure. In one embodiment, the processing circuit 120 is configured to adjust the order of multiple bits in each row of the encoded array 330B to reduce the distribution difference of bit “1” or bit “0” in the encoded array 330B. The adjusted encoded array 330B is called modified array 600.

Referring to FIG. 1, FIG. 3B and FIG. 6, specifically, the processing circuit 120 moves all “bit 1” in the odd rows of the encoded array 330B toward a first direction (e.g., the right side of FIG. 3B). At the same time, all “bit 1” in the even rows in the encoded array 330B are moved toward a second direction (e.g., the left side of FIG. 3B). The first direction and the second direction are opposite, so as to generate the modified array 600. Accordingly, the difference between each column in the modified array 600 will be less than the difference between each column in the encoded array 330B.

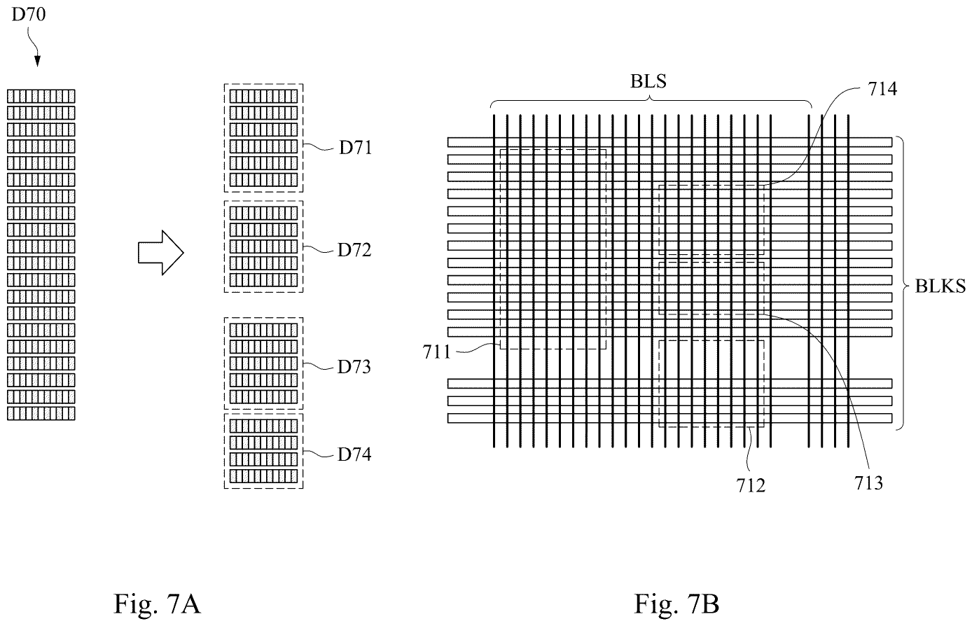

In some embodiments, the processing circuit can flexibly select the memory block(s) to use according to the available regions in the memory array 110. Referring to FIG. 1, FIG. 7A and FIG. 7B, FIG. 7A and FIG. 7B are schematic diagrams in some other embodiments of the present disclosure, wherein FIG. 7B is a simplified partial schematic diagram of the memory array 110. The memory array 110 is coupled to multiple bit lines BLS, and includes multiple memory blocks BLKS. The memory blocks BLKS are respectively arranged in multiple available regions 711-714, and the available regions 711-712 are not adjacent to the available regions 713-714. The processing circuit 120 can select multiple available regions, which are not adjacent to each other, to effectively utilize all the space in the memory array 110.

As mentioned above, since the operation region includes multiple different regions, the processing circuit 120 divides the operation data D70 into multiple section data D71-D74 before performing the memory operation method shown in FIG. 5, and the number of the section data corresponds to the number of the available regions 711~714. Then, the processing circuit 120 provides the section data D71-D74 to the corresponding memory strings of the memory blocks BLKS according to an index sequence of the memory blocks BLKS in the available regions 711~714, so as to perform the vector-matrix multiplication.

The elements, method steps, or technical features in the foregoing embodiments may be combined with each other, and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A memory operation method, comprising:
obtaining, by a processing circuit, an operation code of a vector-matrix multiplication, wherein the processing circuit is coupled to a memory array, the memory array comprises a plurality of memory strings, and the operation code comprises a plurality of operation bits;
converting a first partition of the plurality of operation bits into a first conversion code, wherein a format of the first conversion code is different from a format of the operation code; and
using the first conversion code and a second partition of the plurality of operation bits as an input data, and inputting the input data to a corresponding one of the plurality of memory strings, so that the plurality of memory strings generates an output signal according to a plurality of weight values.

2. The memory operation method of claim 1, wherein the first partition comprises a most significant bit of the plurality of operation bits.

3. The memory operation method of claim 2, wherein the first partition of the plurality of operation bits has higher-order bits compared to the second partition.

4. The memory operation method of claim 1, wherein a number of bits in the first partition accounts for 40% to 60% of the plurality of operation bits.

5. The memory operation method of claim 1, wherein a number of bits in the first partition is larger than a number of bits in the second partition.

6. The memory operation method of claim 5, wherein a number of bits in the first partition accounts accounts for 70% to 95% of the plurality of operation bits.

7. The memory operation method of claim 5, wherein using the first conversion code and the second partition of the plurality of operation bits as the input data comprises:
converting the second partition of the plurality of operation bits into a second conversion code, wherein a format of the second conversion code is equal to the format of the first conversion code.

8. The memory operation method of claim 1, wherein the format of the first conversion code is in unary encoding format.

9. The memory operation method of claim 1, wherein the format of the operation code is in binary encoding format.

10. The memory operation method of claim 1, further comprising:
receiving a plurality of output currents of the plurality of memory strings; and
calculating a current sum value of the plurality of output currents to obtain the output signal.

11. A memory device, comprising:
a memory array coupled to a plurality of word lines and a plurality of bit lines, and comprising a plurality of memory strings;
a sensing circuit coupled to the memory array to obtain an output signal from the memory array; and
a processing circuit coupled to the memory array, and configured to generate an operation code according to an operation data of a vector-matrix multiplication, wherein the operation code comprises a plurality of operation bits;
wherein the processing circuit is further configured for:
converting a first partition of the plurality of operation bits into a first conversion code, wherein a format of the first conversion code is different from a format of the operation code; and
using the first conversion code and a second partition of the plurality of operation bits as an input data, and inputting the input data to a corresponding one of the plurality of memory strings, so that the plurality of memory strings generates an output signal according to a plurality of weight values.

12. The memory device of claim 11, wherein the first partition comprises a most significant bit of the plurality of operation bits.

13. The memory device of claim 12, wherein the first partition of the plurality of operation bits has higher-order bits compared to the second partition.

14. The memory device of claim 11, wherein a number of bits in the first partition accounts for 40% to 60% of the plurality of operation bits.

15. The memory device of claim 11, wherein a number of bits in the first partition is larger than a number of bits in the second partition.

16. The memory device of claim 15, wherein a number of bits in the first partition accounts for 70% to 95% of the plurality of operation bits.

17. The memory device of claim 11, wherein the processing circuit is further configured for:
converting the second partition of the plurality of operation bits into a second conversion code, wherein a format of the second conversion code is equal to the format of the first conversion code.

18. The memory device of claim 11, wherein the format of the first conversion code is in unary encoding format.

19. The memory device of claim 11, wherein the format of the operation code is in binary encoding format.

20. The memory device of claim 11, wherein the sensing circuit is further configured for:
receiving a plurality of output currents of the plurality of memory strings; and
calculating a current sum value of the plurality of output currents to obtain the output signal.
